(19) United States
(12) Patent Application Publication
(10) Pub. No.: US 2020/0049767 A1
(43) Pub. Date: Feb. 13, 2020

(54) SEMICONDUCTOR DEVICES INCLUDING STACKED DIES AND METHODS OF TESTING THE SEMICONDUCTOR DEVICES

(71) Applicant: Samsung Electronics Co., Ltd., Suwon-si (KR)

(72) Inventors: Hyoung-min Kim, Hwaseong-si (KR); Dong-hun Kang, Yongin-si (KR); Myeong-jun Song, Suwon-si (KR)

(21) Appl. No.: 16/285,599

(22) Filed: Feb. 26, 2019

(30) Foreign Application Priority Data
Aug. 7, 2018 (KR) 10-2018-0092054

(51) Int. Cl. G01R 31/317; G01R 31/3177

(52) U.S. Cl. CPC G01R 31/31725; H01L 25/18; G01R 31/3177

(57) ABSTRACT

A semiconductor device includes at least two die stacked on and electrically coupled to an underlying buffer die, which includes a delay control circuit therein. The delay control circuit is configured to: (i) receive and selectively delay test inputs for testing the at least two die, and (ii) transfer test inputs and a delayed version of the test inputs to a first one of the at least two die and a second one of the at least two die, respectively, during test mode operation. The at least two die may include a vertical stack of N (N>2) die on the buffer die and the delay control circuit may include a timing control circuit therein that is configured to supply test inputs to each of the N die in a staged manner so that commencement of respective test modes within each of the N die using the test inputs are out-of-sync relative to each other.

### REFERENCE TO PRIORITY APPLICATION

This application claims the benefit of Korean Patent Application No. 10-2018-0092054, filed Aug. 7, 2018, in the Korean Intellectual Property Office, the entire disclosure of which is hereby incorporated herein by reference.

### BACKGROUND

The inventive concept relates to methods of testing semiconductor devices and, more particularly, to semiconductor devices containing stacked dies and methods of testing same.

Electronic devices have become more compact, higher-performing and of larger-capacity in response to rapid developments in the electronic industry and demands of users. Accordingly, tests of semiconductor devices included in electronic devices have become more complicated. As an example, in a mass production test environment, semiconductor devices such as tens or hundreds of wafer dies (DIEs) or semiconductor packages may be simultaneously tested as devices-under-test (DUT). In addition, in cases where a DUT is a semiconductor device containing a plurality of stacked dies, the number of circuits to be tested is increased and the peak noise in the test environment may become excessive.

### SUMMARY

The inventive concept provides a semiconductor device, which contains dies of a stacked structure and is capable of reducing deterioration in test performance due to peak noise and peak power that may occur in a test environment, and methods of testing same.

According to some embodiments of the inventive concept, a semiconductor device is provided, which includes at least two die stacked on and electrically coupled to an underlying buffer die. This buffer die includes a delay control circuit, which is configured to receive and selectively delay test inputs for testing the at least two die, and to transfer test inputs and a delayed version of the test inputs to a first one of the at least two die and a second one of the at least two die, respectively. These at least two die may be stacked vertically relative to each other on the buffer die.

In addition, in some of these embodiments of the invention, the first one of the at least two die may include at least one through-substrate via (TSV) therein, and the second one of the at least two die may receive test inputs from the buffer die via the at least one through-substrate via within the first one of the at least two die. In some additional embodiments of the invention, the at least two die may be configured as a vertical stack of N die on the buffer die, where N is a positive integer greater than two. In these embodiments, the delay control circuit may include a timing control circuit, which is configured to supply test inputs to each of the N die in a staged manner so that commencement of respective test modes within each of the N die using the test inputs are out-of-sync relative to each other to thereby reduce peak current levels (and peak noise) during testing.

According to another embodiment of the inventive concept, there is provided a semiconductor device including: a buffer die; and first through N^{th} stack dies stacked on the buffer die. These stack die are configured to communicate with the buffer die via through electrodes (where N is an integer equal to or greater than 2). The buffer die includes a delay control circuit, which is configured to receive and delay test inputs for testing the first through N^{th} stack dies. The test inputs may be provided by external test logic. The delay control circuit is also configured to output the delayed test inputs during a test mode of the semiconductor device. And, based on a delay amount set in the delay control circuit, a timing at which the test inputs are transmitted to some of the first through N^{th} stack dies is different from a timing at which the test inputs are transmitted to the others of the first through N^{th} stack dies.

According to another embodiment of the inventive concept, there is provided a method of testing a semiconductor device, which includes an underlying buffer die and a plurality of stacked dies stacked thereon. This test method includes receiving, in a test mode of the semiconductor device, by the buffer die, test inputs for testing the plurality of stack dies from an external test logic, and then delaying, by a delay control circuit provided in the buffer die, the test inputs according to a delay amount set in response to a delay control signal. Then, an operation is performed by the buffer die to transfer the delayed test inputs to the plurality of stack dies via through electrodes. Test signal processing is then performed by the plurality of stacked dies using the test inputs, however, a test execution timing of some of the plurality of stack dies is different from the test execution timing of the other of the plurality of stack dies.

### BRIEF DESCRIPTION OF THE DRAWINGS

Embodiments of the inventive concept will be more clearly understood from the following detailed description taken in conjunction with the accompanying drawings in which:

FIG. 1 is a block diagram illustrating a test system including a semiconductor device according to an embodiment;

FIG. 2 is a block diagram illustrating an implementation example of a delay control circuit included in the semiconductor device of FIG. 1;

FIG. 3 is a block diagram illustrating an implementation example of a semiconductor device according to an embodiment;

FIG. 4 is a diagram illustrating an example of a signal transmission path in a semiconductor device according to an embodiment;

FIG. 5 is a flowchart of a test method of a semiconductor device according to an embodiment;

FIG. 6 is a block diagram illustrating an example in which a semiconductor device is implemented as a high bandwidth memory (HBM) according to an embodiment;

FIGS. 7 and 8 are diagrams illustrating examples in which groups related with delay amount setting in a semiconductor device are variously classified according to embodiments; and

FIG. 9 is a circuit diagram illustrating an implementation example of a delay control circuit according to an embodiment.

### DETAILED DESCRIPTION OF THE EMBODIMENTS

Hereinafter, embodiments of the inventive concept are described in detail with reference to the accompanying drawings.

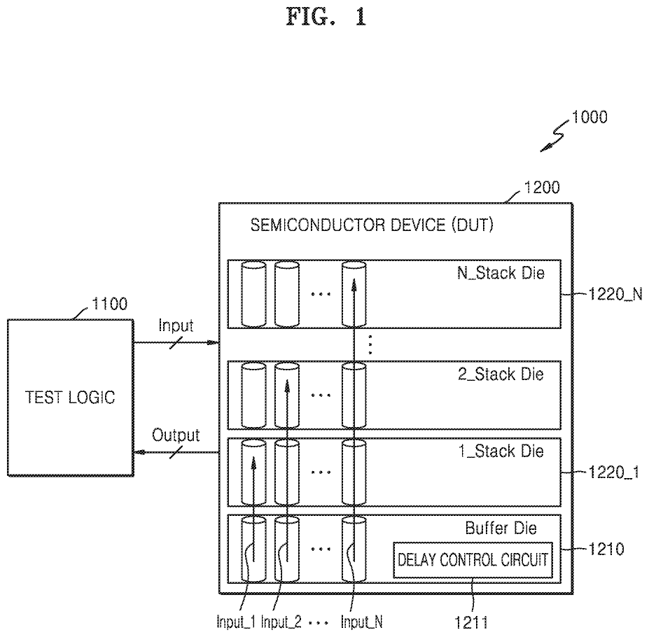

FIG. 1 is a block diagram illustrating a test system 1000 including a semiconductor device 1200 according to an embodiment. Referring to FIG. 1, the test system 1000 for testing a semiconductor device may include, together with a test logic (or tester) 1100, the semiconductor device 1200 as a device under test (DUT) according to an embodiment. In an embodiment, the test system 1000 may be referred to as a test device. In addition, in an embodiment, remaining components of the test system 1000 other than the semiconductor device 1200 may be defined as a test device.

The test system 1000 may include a test board (not illustrated), and the test board may include a DUT mount circuit on which the semiconductor device 1200 is mounted as one or more DUTs. In addition, the test logic 1100 may be mounted on or outside the test board to control a test operation on the semiconductor device 1200. In addition, the DUT mount circuit may include a plurality of sockets for mounting the DUTs, and as a plurality of semiconductor devices 1200 are mounted on the DUT mount circuit in the test system 1000, a parallel test on a plurality of DUTs may be performed.

Although not illustrated in FIG. 1, the test system 1000 may further include a communication device which communicates with an external host requesting a test, a memory that temporarily stores various information related with various tests, and a power supply circuit (not illustrated) for supplying power to various devices included in the test system 1000.

According to an embodiment, the test logic 1100 may be implemented as a semiconductor chip, such as a field programmable gate array (FPGA) and an application specific integrated circuit (ASIC), and an application processor (AP), and may transmit and receive various information according to a parallel communication method between each of the semiconductor devices 1200. For example, the semiconductor device 1200 may include a plurality of semiconductor dies having a stacked structure, and the plurality of semiconductor dies may include a buffer die 1210 communicating with the test logic 1100 outside or an external memory controller (not illustrated), and first through N^{th} stack dies 1220_1 through 1220_N stacked on the buffer die 1210. The test logic 1100 may perform a test in parallel on the first through N^{th} stack dies 1220_1 through 1220_N of the semiconductor device 1200 and in one example, may output in parallel (or, simultaneously) test inputs Input provided to the first through N^{th} stack dies 1220_1 through 1220_N. In addition, the buffer die 1210 may receive in parallel the test inputs Input.

A test process of determining whether the semiconductor device 1200 is defective may be performed at various stages in a semiconductor process and may include, for example, a wafer level test and a test after the wafer level test. The wafer level test may correspond to a test on an individual semiconductor die at a wafer level. In addition, the test after the wafer level test may be a test on a semiconductor die before packaging is performed, or a test on a semiconductor package in which one semiconductor die (or semiconductor chip) is packaged. Alternatively, the test on the semiconductor package may be a test on a semiconductor package including a plurality of semiconductor chips.

According to an embodiment, when the test system 1000 illustrated in FIG. 1 is a device which performs the wafer level test, the semiconductor device 1200 may be a semiconductor die formed on a semiconductor wafer, and the semiconductor die may include the buffer die 1210 and the first through N^{th} stack dies 1220_1 through 1220_N which are formed through the semiconductor process. Alternatively, when the test system 1000 illustrated in FIG. 1 is a device for testing the semiconductor package, the semiconductor device 1200 may include a semiconductor package in which a plurality of semiconductor dies (or semiconductor chips) are vertically stacked and packaged.

The semiconductor device 1200 may be a device which performs various functions and may include a memory device including a memory cell array. For example, the memory device may include dynamic random access memory (DRAM) such as double data rate (DDR) synchronous DRAM (SDRAM), low power DDR (LPDDR), graphics DDR (GDDR) SDRAM, and rambus DRAM (RDRAM). Alternatively, the memory device may include a nonvolatile memory such as a flash memory, magnetic RAM (MRAM), ferroelectric RAM (FeRAM), phase change RAM (PRAM), and resistive RAM (ReRAM).

According to an embodiment, the test inputs Input from the test logic 1100 may be provided in parallel to the buffer die 1210 of the semiconductor device 1200. In addition, the buffer die 1210 may communicate with the first through N^{th} stack dies 1220_1 through 1220_N via a plurality of through electrodes and may communicate with the first through N^{th} stack dies 1220_1 through 1220_N via, for example, a plurality of through silicon vias (TSVs). FIG. 1 illustrates an example in which a plurality of test inputs Input are provided to the buffer die 1210, and in an example, the number of test inputs Input may correspond to the number of first through N^{th} stack dies 1220_1 through 1220_N. Alternatively, the test input Input may be commonly provided to the first through N^{th} stack dies 1220_1-1220_N, and the buffer die 1210 may branch the test input Input and provide the branched test input Input to the first through N^{th} stack dies 1220_1 through 1220_N. Alternatively, when each of the first through N^{th} stack dies 1220_1 through 1220_N includes a plurality of channels that perform independent interfaces and a separate test operation is performed for each of the plurality of channels, the number of test inputs Input may be greater than the number of first through N^{th} stack dies 1220_1 through 1220_N.

The buffer die 1210 may include a delay control circuit 1211, which delays the received test inputs Input and provides the delayed first through N^{th} test inputs Input_1 through Input_N to the first through N^{th} stack dies 1220_1 through 1220_N. In one example, the delay control circuit 1211 may perform a delay operation on each of the test inputs Input that are provided respectively to the first through N^{th} stack dies 1220_1 through 1220_N, and accordingly, timings at which the test inputs Input are provided to some of the first through N^{th} stack dies 1220_1 through 1220_N may be different from timings at which the test inputs Input are provided to the other of the first through N^{th} stack dies 1220_1 through 1220_N. Alternatively, based on the delay operation of the delay control circuit 1211, the timings at which the first through N^{th} delayed test inputs Input_1 through Input_N are provided respectively to the first through N^{th} stack dies 1220_1 through 1220_N may all be different from each other.

The delay control circuit 1211 may respectively output the first through N^{th} delayed test inputs Input_1 through Input_N to the first through N^{th} stacked dies 1220_1 through 1220_N through a delay processing operation on the test inputs Input. The first through N^{th} delayed test inputs Input_1 through Input_N may be provided respectively to target circuits which perform signal processing for a test operation in the first through N^{th} stack dies 1220_1 through 1220_N.

According to an embodiment, the delay control circuit 1211 may delay the test inputs Input for the first through N^{th} stack dies 1220_1 through 1220_N according to different amounts of delay. Accordingly, while the test inputs Input are provided in parallel (or simultaneously) to the buffer die 1210, the first through N^{th} stacked dies 1220_1 through 1220_N may receive the first through N^{th} delayed test inputs Input_1 through Input_N that have been delayed at different timings and may perform the test operation. In other words, the first through N^{th} stacked dies 1220_1 through 1220_N may perform the test at different timings regardless of timings at which the buffer die 1210 receives the test inputs Input. Accordingly, large peak noise and/or large peak current that occurs due to tests simultaneously performed by the first through N^{th} stack dies 1220_1 through 1220_N may be dispersed, and deterioration of characteristics of the DUT in a parallel test environment may be prevented.

According to an embodiment, the delay control circuit 1211 may set a delay amount corresponding to each stack die in response to a certain delay control signal in a test mode of the semiconductor device 1200. For example, the semiconductor device 1200 may include control logic generating various control signals therein and in the test mode, may generate the delay control signal for setting the delay amount described above. Alternatively, in the test mode, the delay control circuit 1211 may receive the delay control signal described above from the test logic 1100 and set the delay amount in response thereto. In other words, the delay control circuit 1211 may be configured to be capable of programming the delay amount for each of the first through N^{th} stack dies 1220_1 through 1220_N, and accordingly, the timings at which the test inputs Input are transmitted to some of the first through N^{th} stack dies 1220_1 through 1220_N may be different from the timings at which the test inputs Input are transmitted to the other of the first through N^{th} stack dies 1220_1 through 1220_N.

According to an embodiment, the first through N^{th} stack dies 1220_1 through 1220_N may be grouped into two or more groups, and each group may include one or more stack dies. In addition, as the delay amount of the delay control circuit 1211 is set differently on a group basis, the test inputs Input may be simultaneously provided to the stack dies which belong to the same group. On the other hand, the test inputs Input may be provided at different timings to the stack dies which belong to different groups.

When any one of the stack dies includes a plurality of channels for receiving the test inputs Input via independent interfaces, the plurality of channels of each of the first through N^{th} stack dies 1220_1 through 1220_N may be tested at different timings. In one embodiment, the delay control circuit 1211 may be arranged in the buffer die 1210 in correspondence to each of the plurality of channels, and the delay control circuits 1211 of the plurality of channels may delay the test inputs Input according to different delay amounts.

According to the embodiment described above, it may be possible to prevent a simultaneous and identical operation, of a plurality of stack dies of the semiconductor device 1200, which consumes a large amount of current in the parallel test environment, and accordingly, peak current and peak noise of the test system 1000 may be reduced and characteristics deterioration of the DUT in the test environment may be prevented. In addition, since, from a viewpoint of the test logic 1100, it is not needed that the plurality of test inputs Input are sequentially provided to the semiconductor device 1200 or that some stack dies selectively perform tests, deterioration of the test speed in the parallel test environment may be prevented.

On the other hand, as the first through N^{th} stack dies 1220_1 through 1220_N of the semiconductor device 1200 sequentially perform processing operations by using the first through N^{th} delayed test inputs Input_1 through Input_N, the test logic 1100 may receive sequentially test results Outputs from the first through N^{th} stack dies 1220_1 through 1220_N and determine whether the first through N^{th} stack dies 1220_1 through 1220_N are defective based on a certain logic process. For example, the test logic 1100 may determine whether the first through N^{th} stack dies 1220_1 through 1220_N are defective, based on determination of whether patterns of the test input Input provided to the semiconductor device 1200 are the same as patterns of the test results Outputs provided from the first through N^{th} stacked dies 1220_1 through 1220_N.

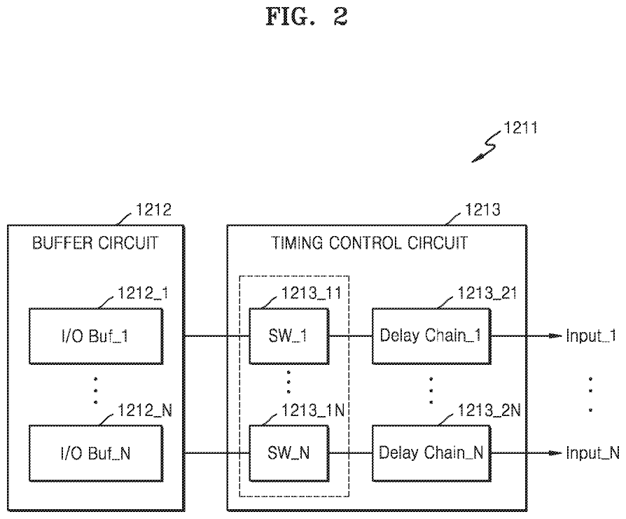

FIG. 2 is a block diagram illustrating an implementation sample of the delay control circuit 1211 included in the semiconductor device 1200 of FIG. 1. Referring to FIGS. 1 and 2, the delay control circuit 1211 may include a buffer circuit 1212 receiving the test inputs Input, and a timing control circuit 1213 which outputs the first through N^{th} delayed test inputs Input_1 through Input_N by performing the delay processing on the test inputs Input that are output from the buffer circuit 1212. As an example, the buffer circuit 1212 may include first through N^{th} input/output (I/O) buffers 1212_1 through 1212_N for receiving in parallel the test inputs Input corresponding to the first through N^{th} stack dies 1220_1 through 1220_N. In addition, the timing control circuit 1213 may include first through N^{th} switches 1213_11 through 1213_1N and first through N^{th} delay chains 1213_21 through 1213_2N, which are arranged respectively corresponding to the first through N^{th} stack dies 1220_1 through 1220_N.

According to an embodiment, each of the first through N^{th} delay chains 1213_21 through 1213_2N may include a plurality of delay circuits, and the delay amount may be programmed by the plurality of delay circuits. As an example, in the test mode of the semiconductor device 1200, the delay amount of each of the first through N^{th} delay chains 1213_21 through 1213_2N may be programmed by various methods such as fuse cutting, however, other programming techniques (e.g., PROMs) may also be utilized. For example, in the plurality of delay circuits included in each of the first through N^{th} delay chains 1213_21 through 1213_2N, the number of delay circuits through which the test inputs Input pass according to the above-described delay control signal may be adjusted, and based thereon, the delay amounts of the first through N^{th} delay chains 1213_21 through 1213_2N may be set to be different from each other. The first through N^{th} switches 1213_11 through 1213_1N may be selectively turned on in response to a mode control signal (not illustrated) in the test mode, and accordingly, the control operation may be performed in the test mode such that the test inputs Input are delayed according to the first through N^{th} delay chains 1213_21 through 1213_2N. As an example, the mode control signal may be generated by the control logic (not illustrated) in the buffer die 1210 or may be generated in the external test logic 1100 and provided to the buffer die 1210.

The semiconductor device 1200 may perform a certain signal processing by using the received test input Input and may provide a result of the certain signal processing as the test outputs Output to the external test logic. Although not illustrated in FIGS. 1 and 2, the test outputs Output may be provided to the buffer circuit 1212 without the delay processing but via separate paths and be transmitted to the external test logic 1100.

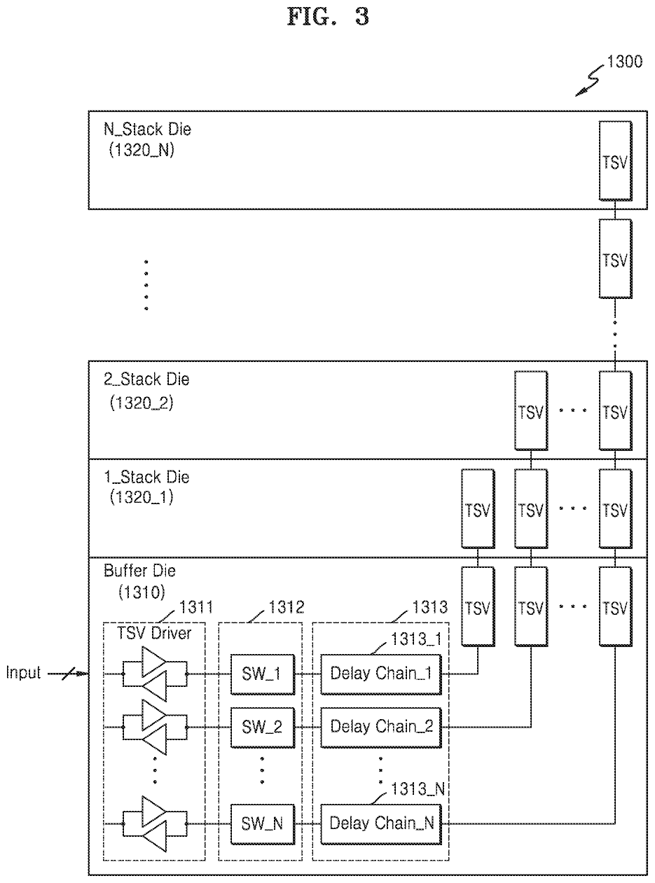

FIG. 3 is a block diagram illustrating an implementation example of a semiconductor device 1300 according to an embodiment. In the following embodiments, for convenience of explanation, both test information provided to a semiconductor device and test information delayed by the semiconductor device are referred to as test inputs. In other words, the test inputs provided to stack dies may correspond to information in which the test inputs provided to a buffer die are delayed.

Referring to FIG. 3, the semiconductor device 1300 may include a buffer die 1310 and N stack dies or first through N^{th} stack dies 1320_1 through 1320_N which are stacked on the buffer die 1310. According to the embodiments described above, the buffer die 1310 may communicate with the first through N^{th} stack dies 1320_1 through 1320_N via a plurality of through electrodes, and communication may be performed via, for example, through-substrate vias (TSVs) (a/k/a through-silicon vias).

The buffer die 1310 may include a buffer circuit receiving signals provided to the first through N^{th} stack dies 1320_1 through 1320_N via TSVs, and the buffer circuit may be referred to as a TSV driver 1311 from a viewpoint of performing a function of driving the TSVs. In addition, the buffer die 1310 may include a switch block 1312 for receiving the test inputs Input via the TSV driver 1311 in the test mode of the semiconductor device 1300, and a delay chain block 1313 for receiving the test inputs Input and performing the delay processing on the test inputs Input. In addition, the delay chain block 1313 may include N delay chains or first through N^{th} delay chains 1313_1 through 1313_N arranged respectively corresponding to the first through N^{th} stack dies 1320_1 through 1320_N, and each of the first through N^{th} delay chains 1313_1 through 1313_N may perform the delay processing on the test input Input that is provided to each of corresponding stack dies. In addition, each of the N delay chains (1313_1 through 1313_N) may have a programmable delay amount, and for example, each of the N delay chains (1313_1 through 1313_N) may include the plurality of delay circuits, and the delay amount may be adjusted by varying the number of delay circuits which are used for the delay processing of the test inputs Input.

When a semiconductor device including a plurality of dies having a TSV structure is tested according to a structure of components illustrated in FIG. 3, test execution timings of the first through N^{th} stack dies 1320_1 through 1320_N may be adjusted differently so that noise of the peak current is dispersible and thus, a power supply constraint of the test system 1000 can be reduced. In addition, since it is possible to perform the parallel test on the stack dies without having to divide and test some of the plurality of stack dies, more stack dies may be tested simultaneously and the time required for tests may be reduced.

In the embodiment illustrated in FIG. 3, a plurality of TSVs may be formed and allocated to each of the N stack dies (1320_1 through 1320_N), and as the test input Input is transmitted via respectively assigned TSVs, the TSVs may transfer the test inputs Input that are delayed by different delay amounts. In addition, in the embodiment of FIG. 3, an example is illustrated in which the TSVs are formed per die and the TSVs of different dies are electrically connected to each other via a certain conduction material (for example, via contacts). As an example, the TSV may be formed such that N stack dies (1320_1 through 1320_N) are stacked on the buffer die 1310 and then the TSV penetrates through all the dies.

On the other hand, in the above-described embodiment, the test inputs Input may include various pieces of information. As an example, the semiconductor device 1300 may correspond to a memory device including a memory cell array, and a test may be performed by writing data having a certain pattern into the semiconductor device 1300 and reading the written data, wherein the test inputs Input include at least some of commands, addresses, and data. According to an embodiment, the buffer die 1310 of the semiconductor device 1300 may include a buffer circuit (or TSV driver) receiving a command, a buffer circuit receiving an address, and a buffer circuit receiving data. In addition, delay control circuits according to embodiments of the inventive concept may be arranged to apply a delay in transmitting at least one of the command, the address, and the data to the N stack dies (1320_1 through 1320_N).

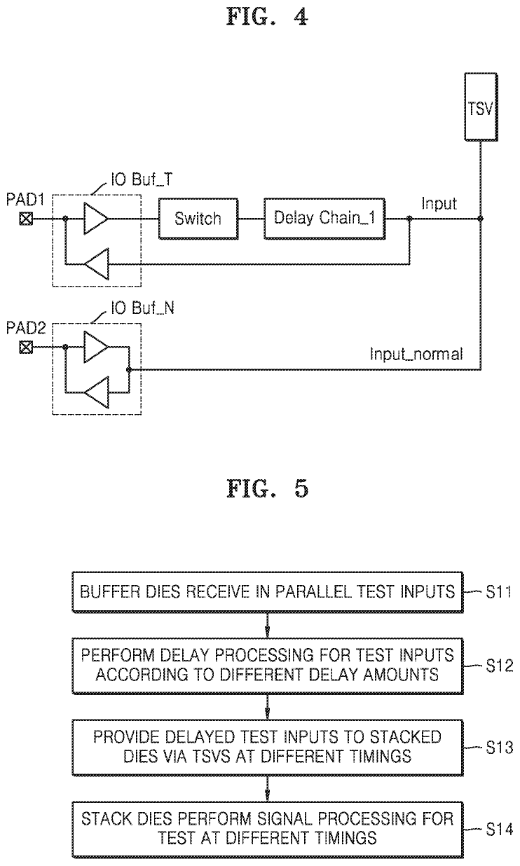

FIG. 4 is a diagram illustrating an example of a signal transmission path in a semiconductor device according to an embodiment. In FIG. 4, it is illustrated that a test input in a test mode and a normal input in a normal mode are received via different pads. As another example, a semiconductor device may be implemented such that the test input in the test mode and the normal input in the normal mode are received via the same pad, wherein a circuit is configured such that delay of the normal input in the normal mode is not applied by adjusting a delay amount of a delay control circuit.

Referring to FIG. 4, the semiconductor device may include a first IO buffer IO Buf_T receiving the test input Input via a first pad PAD 1 in the test mode, and a second IO buffer IO Buf_N receiving the normal input Input_normal via a second pad PAD 2 in the normal mode. Although FIG. 4 illustrates one first pad PAD 1 receiving the test input Input and one second pad PAD 2 receiving the normal input Input_normal, the semiconductor device may include a plurality of first pads PAD 1 receiving the test input Input and a plurality of second pads PAD 2 receiving the normal input Input_normal. As an example, the semiconductor device may transmit and receive information via the test logic (or tester) 1100 and the first pad PAD 1 and may transmit and receive information via an external memory controller and the second pad PAD 2.

According to one embodiment, a delay chain Delay Chain_1 may be arranged as a component of the delay control circuit 1211 on a path through which the test input Input is transmitted via the first IO buffer IO Buf_T, and the delay amount of the delay control circuit 1211 may be set in response to the delay control signal. The test output Output may be generated after a certain delay time after the test input Input is provided to the stack die. According to an embodiment, the test output Output may be transmitted to the outside via the first pad PAD 1 without going through the delay chain Delay Chain_1.

In addition, without the delay processing for the normal input Input_normal in the normal mode, the test input Input may be transmitted to the same core die via the same TSV as the TSV to which the test input Input has been transmitted in the above-described test mode.

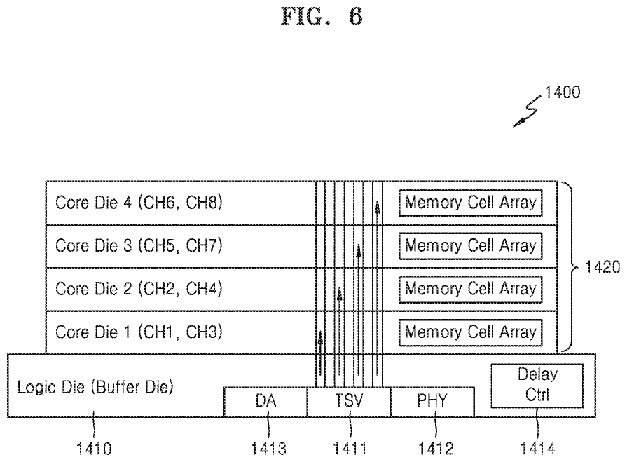

FIG. 5 is a flowchart of a test method of a semiconductor device according to an embodiment. Referring to FIG. 5, the semiconductor device may include a plurality of semiconductor dies (or semiconductor chips) of a stacked structure, and a plurality of semiconductor dies may communicate with each other via through electrodes such as TSVs. In addition, the plurality of semiconductor dies may be tested separately in a test mode, and accordingly, an external test logic may generate test inputs for testing the plurality of semiconductor dies and provide the generated test inputs to the semiconductor device. The plurality of semiconductor dies may include a buffer die communicating with the external test logic, and in addition, the plurality of semiconductor dies may further include stacked dies (or core dies) which receive the test input via the buffer die and generate a test output.

In a parallel test environment, the plurality of semiconductor devices may be placed on a DUT mounting circuit of a test system, etc., and the stack dies included in each semiconductor device may be tested separately. Accordingly, the test inputs for testing the plurality of stack dies of any one semiconductor device may be received in parallel (or simultaneously) by the buffer die from an external test logic (S11).

The buffer die of the semiconductor device may include a delay control circuit performing a delay process on the test input, and the delay control circuit may include timing control circuits for delaying the test inputs provided to the plurality of stack dies according to different delay amounts. The delay control circuit may receive a delay control signal generated by the semiconductor device or provided from the external test logic, and the timing control circuits may be set differently in response to the delay control signal. Accordingly, the delay process according to different delay amounts may be performed on the test inputs provided to the stack dies (S12).

The test inputs delayed as described above may be provided to the plurality of stack dies via the TSVs that are independently arranged for each stack die (S13), and the plurality of stacked dies may perform signal processing for testing at different timings by using the received test inputs (S14). According to an embodiment, the test outputs from the plurality of stacked dies may be generated at different timings and may be sequentially transmitted to the external test logic without separate delay processing on the test output.

Although the flow chart of FIG. 5 describes that the test inputs are provided at different timings to the plurality of stack dies, embodiments of the inventive concept, as in the previous embodiments, may apply different delay amounts to the test inputs for each group by grouping the plurality of stack dies and a plurality of channels in various manners.

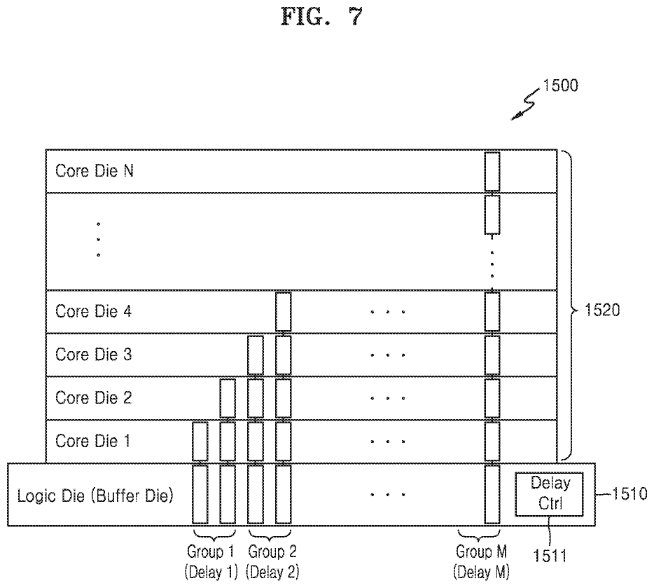

FIG. 6 is a block diagram illustrating an example in which a semiconductor device is implemented as a high bandwidth memory (HBM) 1400 according to an embodiment. Referring to FIG. 6, the HBM 1400 may include the plurality of semiconductor dies, and the plurality of semiconductor dies may include a logic die (or buffer die) 1410 and one or more core dies 1420. The core dies 1420 may correspond to the stack dies in the embodiments described above. The HBM 1400 may have an increased bandwidth by including first through eighth channels CH1 through CH8 having independent interfaces. In FIG. 6, an example is illustrated in which the HBM 1400 includes four core dies 1420 and each of the core dies 1420 includes two channels therein. However, the number of core dies 1420 and the number of channels (CH1 through CH8) provided in the HBM 1400 may be variously changed.

The logic die (or buffer die) 1410 may include a TSV region 1411, a physical (PHY) region 1412, and a direct access (DA) region 1413. In addition, the logic die 1410 may further include a control logic (not illustrated) for controlling the overall operation within the HBM 1400. For example, the logic die 1410 may perform an internal control operation of the HBM 1400 in response to commands from an external controller. In addition, according to the above-described embodiments, a delay control (Delay Ctrl) circuit 1414 for delaying the test input may further be included in the logic die 1410.

The TSV region 1411 may correspond to a region where the TSVs for communicating with the core dies 1420 are formed. In addition, the PHY region 1412 may include a plurality of 10 circuits for communicating with the external controller, and the DA region 1413 may directly communicate with an external tester via conductive measures arranged on an outer surface of the HBM 1400 in the test mode for the HBM 1400. Various signals provided from the tester may be provided to the core dies 1420 through the DA region 1413 and the TSV region 1411. In above-described embodiments, the test input from the external tester may be provided to the Delay Ctrl circuit 1414 via the DA region 1413, and the delayed test input may be provided to the core dies 1420 via the TSV region 1411.

According to an embodiment of the inventive concept, the Delay Ctrl circuit 1414 may receive and delay a test input that is commonly provided to the first through eighth channels CH1 through CH8, and then, provide the delayed test input to the first through eighth channels CH1 through CH8. Alternatively, the Delay Ctrl circuit 1414 may receive and delay test inputs that are provided separately to the first through eighth channels CH1 through CH8 and output the delayed test inputs through the delay processing operation on the test inputs.

According to an embodiment, the test inputs may be provided at various timings to the first through eighth channels CH1 through CH8. For example, the timings of providing the test inputs may be set differently depending on positions of the core dies 1420, or the timings of providing the test inputs may be set differently per channel for the first through eighth channels CH1 through CH8. Alternatively, the plurality of core dies 1420 may be classified into one or more groups, and the timings of providing the test inputs may be set differently per group. Alternatively, regardless of stacked positions of the core dies 1420, the first through eighth channels CH1 through CH8 may be classified into one or more channel groups, and the timings of providing the test inputs may be set different from each other per channel group.

Taking the first core die Core Die 1 as an example, the test inputs from the logic die 1410 may be provided to the first and third channels CH1 and CH3 of the first core die Core Die 1 via separate TSVs, respectively, and the delay amounts for the test inputs provided to the first and third channels CH1 and CH3 may be set differently from each other. Accordingly, the first channel CH1 and the third channel CH3 may respectively perform the test operation by using the test input at different timings.

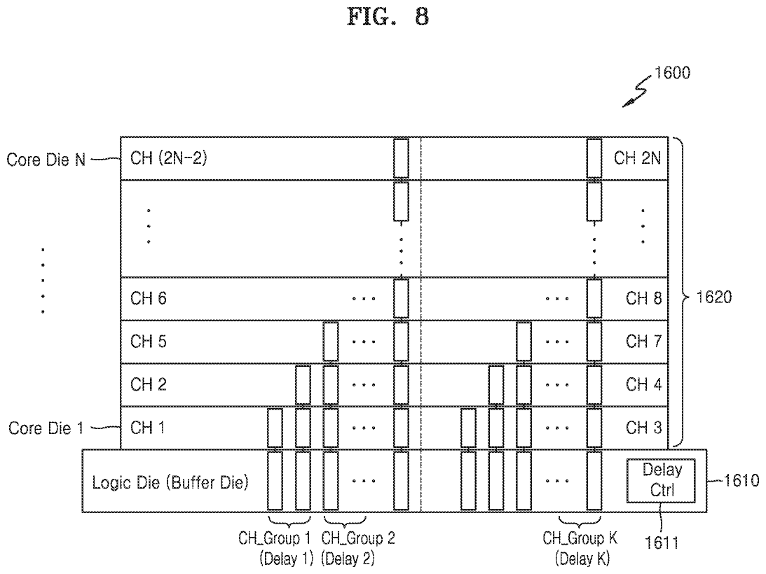

FIGS. 7 and 8 are diagrams illustrating examples in which groups related with delay amount setting in semiconductor devices 1500 and 1600 are variously classified according to embodiments. FIGS. 7 and 8 illustrate examples in which semiconductor devices 1500 and 1600 correspond to the HBMs described above and the HBM includes N core dies. Referring to FIG. 7, the semiconductor device 1500 may include a logic die 1510 and first through N^{th} core dies 1520 stacked thereon. In addition, the logic die 1510 may communicate with the first through N^{th} core dies 1520 via a plurality of TSVs, and the different core dies may constitute different channels. In addition, a plurality of channels provided in the semiconductor device 1500 may communicate with the logic die 1510 independently via the TSVs.

According to an embodiment, the first through N^{th} core dies 1520 may be classified into two or more groups based on positions of the first through N^{th} core dies. In the embodiment illustrated in FIG. 7, similarly to the case in which the first and second core dies Core Die 1 and Core Die 2 are divided into a first group Group 1, and the third and fourth core dies Core Die 3 and Core Die 4 are classified into a second group Group 2, the first through N^{th} core dies 1520 may be classified into the M groups. However, the embodiments of the inventive concept may be variously grouped in other manners. As an example, the number of core dies included in each group may be classified differently.

In addition, the logic die 1510 may include a Delay Ctrl circuit 1511 according to the embodiments described above, and the test inputs provided to the first through N^{th} core dies 1520 may be delayed according to a delay amount set by the Delay Ctrl circuit 1511. As one example, the test input may be provided to core dies of the first group Group 1 after being delayed by a first delay amount Delay 1, and the test input may be provided to core dies of the M^{th} group Group M after being delayed by an M^{th} delay amount Delay M.

Referring to FIG. 8, the semiconductor device 1600 may include a logic die 1610 and first through N^{th} core dies 1620 stacked thereon. In addition, an example is illustrated in which the logic die 1610 communicates with the first through N^{th} core dies 1620 via the plurality of TSVs, and each core die includes two channels.

According to an embodiment, the first through N^{th} core dies 1620 may be classified into two or more channel groups based on positions of the channels. According to the embodiment illustrated in FIG. 8, even though the channels are arranged on the same core die, the channels may be classified into different channel groups due to the difference of the channels. In an example, the some channels (for example, CH1 and CH2) of the first and second core dies Core Die 1 and Core Die 2 may be classified into the same channel group, and the other channels (for example, CH3 and CH4) of the first and second core dies Core Die 1 and Core Die 2 may be classified into another same channel group. In other words, the first and third channels CH1 and CH3 of the first core die Core Die 1 may be classified into different channel groups. In the embodiment illustrated in FIG. 8, an example is illustrated in which the channels included in two core dies are classified into the same channel group, and the semiconductor device 1600 includes a total of K channel groups. However, embodiments of the inventive concept may classify channels into channel groups based on various different methods.

On the other hand, the logic die 1610 may include the Delay Ctrl circuit 1611 according to the above-described embodiments, and the test inputs provided to the first through N^{th} core dies 1620 may be delayed according to the delay amount of the Delay Ctrl circuit 1611 based on the channel groups. As an example, the test input may be provided to the core dies of a first channel group CH_Group 1 after being delayed by a first delay amount Delay 1 and may be provided to core dies of the K^{th} channel group CH_Group K after being delayed by a K^{th} delay amount Delay K.

In FIG. 8, it is illustrated that channels included in at least two core dies are included in the same channel group, but the embodiments of the inventive concept need not be limited thereto. For example, a different delay amount may be set for each core die and each channel. In this case, a different delay amount may be set corresponding to each of 2*N channels so that the test inputs are provided to the 2*N channels at different timings.

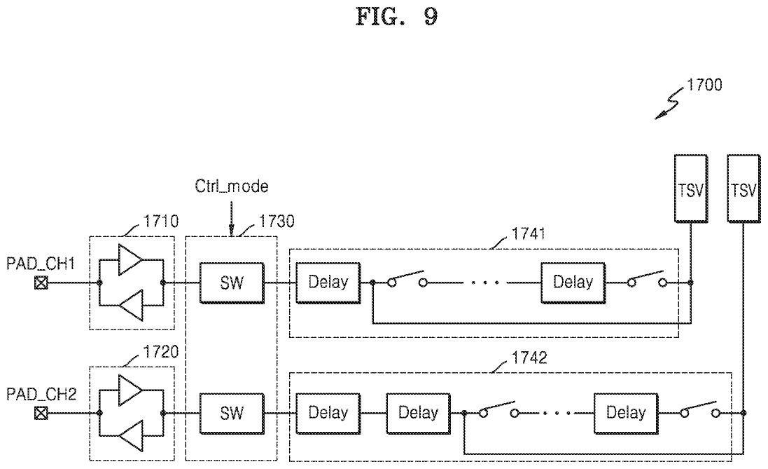

FIG. 9 is a circuit diagram of an implementation example of a delay control circuit according to an embodiment. In FIG. 9, an example is illustrated in which different delay amounts are applied to different channels (for example, the first and second channels CH1 and CH2).

Referring to FIG. 9, in the test mode, the semiconductor device 1700 may include a buffer circuit 1710 receiving a test input for the first channel CH1 via a first pad PAD_CH1 and a buffer circuit 1720 receiving a test input for the second channel CH2 via a second pad PAD_CH2. In addition, the semiconductor device 1700 may include a switch block 1730 including switches which are selectively turned on in the test mode, and the switches of the switch block 1730 may be switched in response to a mode control signal Ctrl_mode that is generated by the semiconductor device 1700 or provided from the external test logic.

In addition, the semiconductor device 1700 may further include a first Delay Chain_1741 for delaying the test input for the first channel CH1 and a second Delay Chain_1742 for delaying the test input for the second channel CH2, and each of the first and second Delay Chains 1741 and 1742 may include a plurality of delay circuits. The test inputs delayed by the first and second Delay Chains 1741 and 1742 may be provided to the core dies via the TSVs. In the embodiment illustrated in FIG. 9, the switch block 1730 and the first and second Delay Chains 1741 and 1742 may be components to be included in the Delay Ctrl circuits in the above-described embodiments.

According to an embodiment, each of the first and second Delay Chains 1741 and 1742 may include a plurality of switches connected to output ends of the plurality of delay circuits, and the plurality of switches may electrically connect the output ends of the plurality of delay circuits to the TSVs. A position of the output end of the delay circuit connected to the TSV may be varied according to the delay control signal in the above-described embodiment, and based on this, the delay amount of the test input may be adjusted. For example, as the number of delay circuits through which the test input for the first channel CH1 passes is less than the number of delay circuits through which the test input for the second channel CH2 passes, the delay amount of the test input for the first channel CH1 may be relatively less than the delay amount of the test input for the second channel CH2.

According to a semiconductor device including dies having a stack structure of the inventive concept and test method thereof, it may be possible to reduce peak current and/or peak noise in an environment for testing the semiconductor device including a plurality of dies and to prevent deterioration of the test speed.

As described above, embodiments have been disclosed in the drawings and the specification. While the embodiments have been described herein with reference to specific terms, it should be understood that they have been used only for the purpose of describing the technical idea of the inventive concept and not for limiting the scope of the inventive concept as defined in the claims. Thus, those with ordinary skill in the art will appreciate that various modifications and equivalent embodiments are possible without departing from the scope of the inventive concept. Therefore, the true scope of protection of the inventive concept should be determined by the technical idea of the appended claims.

What is claimed is:

1. A semiconductor device, comprising:
at least two die stacked on and electrically coupled to an underlying buffer die, which comprises a delay control circuit therein, said delay control circuit configured to receive and selectively delay test inputs for testing said at least two die, and to transfer test inputs and a delayed version of the test inputs to a first one of said at least two die and a second one of said at least two die, respectively.

2. The semiconductor device of claim 1, wherein said at least two die are stacked vertically relative to each other on said buffer die.

3. The semiconductor device of claim 2, wherein the first one of said at least two die comprises at least one through-substrate via therein; and wherein the second one of said at least two die receives test inputs from the buffer die via the at least one through-substrate via within the first one of said at least two die.

4. The semiconductor device of claim 3, wherein said at least two die comprises a vertical stack of N die on the buffer die, where N is a positive integer greater than two;
and wherein said delay control circuit comprises a timing control circuit therein that is configured to supply test inputs to each of the N die in a staged manner so that commencement of respective test modes within each of the N die using the test inputs are out-of-sync relative to each other.

5. The semiconductor device of claim 2, wherein said at least two die comprises a vertical stack of N die on the buffer die, where N is a positive integer greater than two;
and wherein said delay control circuit comprises a timing control circuit therein that is configured to supply test inputs to each of the N die in a staged manner so that commencement of respective test modes within each of the N die using the test inputs are out-of-sync relative to each other.

6. A semiconductor device, comprising:
a buffer die; and
first through N^{th} stack dies stacked on the buffer die and configured to communicate with the buffer die via through electrodes (where N is an integer equal to or greater than 2),
wherein the buffer die comprises a delay control circuit configured to receive and delay test inputs for testing the first through N^{th} stack dies from an external test logic, and output the delayed test inputs, in a test mode of the semiconductor device,
wherein, based on a delay amount set in the delay control circuit, a timing at which the test inputs are transmitted to some of the first through N^{th} stack dies is different from a timing at which the test inputs are transmitted to the others of the first through N^{th} stack dies.

7. The semiconductor device of claim 6, wherein the buffer die is configured to simultaneously receive the test inputs provided to the first through N^{th} stack dies, and the delay control circuit is configured to delay and output the test inputs according to different delay amounts.

8. The semiconductor device of claim 6, wherein the first through N^{th} stack dies are classified into first through M^{th} groups (where M is an integer less than N), and the test inputs are transmitted to stack dies comprised in an identical group at an identical timing while the test inputs are transmitted to stack dies comprised in different groups at a different timing.

9. The semiconductor device of claim 6, wherein the delay control circuit comprises: first through N^{th} switches arranged correspondingly to the first through N^{th} stack dies, the first through N^{th} switches configured to receive and switch the test inputs;
and first through N^{th} delay chains configured to receive the test inputs via the first through N^{th} switches, the first through N^{th} delay chains configured to delay and output the test inputs according to delay amounts that are respectively set.

10. The semiconductor device of claim 9, wherein the first through N^{th} switches are configured to be selectively turned on in the test mode in response to a mode control signal from the test logic.

11. The semiconductor device of claim 9, wherein each of the first through N^{th} delay chains comprises a plurality of delay circuits, and the delay amount of each of the first through N^{th} delay chains is set by varying the number of delay circuits configured to delay the test inputs according to the delay control signal from the test logic.

12. The semiconductor device of claim 6, wherein the buffer die is configured to communicate with the first through N^{th} stack dies via through silicon vias (TSVs) formed in each of the first through N^{th} stack dies.

13. The semiconductor device of claim 12, wherein the semiconductor device comprises a high bandwidth memory (HBM), and each of the first through N^{th} stack dies comprises at least two channels configured to communicate with the outside via independent interfaces.

14. The semiconductor device of claim 13, wherein the first stack die comprises a first channel and a second channel, and the delay control circuit comprises a first delay chain corresponding to the first channel and a second delay chain corresponding to the second channel, wherein a timing at which the test input is transmitted to the first channel and a timing at which the test input is transmitted to the second channel are different from each other.

15. The semiconductor device of claim 6, wherein the buffer die and the first through N^{th} stack dies comprise semiconductor chips of a stacked structure, and the semiconductor device comprises a semiconductor package in which the semiconductor chips are packaged.

16. A test method of a semiconductor device comprising a buffer die and a plurality of stacked dies stacked thereon, the test method comprising:
receiving, in a test mode of the semiconductor device, by the buffer die, test inputs for testing the plurality of stack dies from an external test logic;
delaying, by a delay control circuit provided in the buffer die, the test inputs according to delay amounts set in response to a delay control signal;
transferring, by the buffer die, the delayed test inputs to the plurality of stack dies via through electrodes; and
performing, by the plurality of stacked dies, test signal processing by using the test inputs,
wherein a test execution timing of some of the plurality of stack dies is different from the test execution timing of the other of the plurality of stack dies.

17. The test method of claim 16, wherein the delay control signal is provided from the external test logic in the test mode.

18. The test method of claim 16, wherein the delay control circuit comprises a plurality of delay chains corresponding to the plurality of stack dies, and as the delay amounts of the plurality of delay chains are set differently according to the delay control signal, timings at which the test inputs are transmitted to the plurality of stacked dies are different from each other.

19. The test method of claim 16, wherein the semiconductor device comprises a high bandwidth memory (HBM), and each of the plurality of stacked dies comprises at least two channels configured to communicate with the outside via independent interfaces.

20. The test method of claim 19, wherein any one stack die of the plurality of stack dies comprises a first channel and a second channel, and the delay control circuit comprises a first delay chain corresponding to the first channel and a second delay chain corresponding to the second channel, wherein the delay amounts of the first delay chain and the second delay chain are set to be different from each other.
